(19) United States
(12) Patent Application Publication
(10) Pub. No.: US 2014/0126168 A1
(43) Pub. Date: May 8, 2014

(54) WIRELESS MODULE

(71) Applicant: PANASONIC CORPORATION, Osaka (JP)

(72) Inventors: Suguru Fujita, Tokyo (JP); Ryosuke Shiozaki, Kanagawa (JP)

(73) Assignee: PANASONIC CORPORATION, Osaka (JP)

(21) Appl. No.: 14/131,551

(22) PCT Filed: Nov. 29, 2012
(86) PCT No.: PCT/JP2012/007682

§ 371 Date: Jan. 8, 2014

(30) Foreign Application Priority Data
Dec. 2, 2011 (JP) 2011-265019
Dec. 7, 2011 (JP) 2011-268042

(51) Int. Cl. H05K 1/02

(52) U.S. Cl. CPC H05K 1/025; H05K 1/0298
USPC 361/777

(57) ABSTRACT

A wireless module includes a first board (11) on which a mounting component of a wireless circuit is mounted, and a second board (12) which is laminated on the first board (11). The first board (11) and the second board (12) are electrically connected together by a connecting member (18) such as a Cu core ball. Laterally to the connecting member (18), a conductive member (23) for impedance adjustment is provided at a position at a predetermined distance from the connecting member (18), such that the signal path of the connecting member (18) has predetermined impedance.

### TECHNICAL FIELD

The present disclosure relates to a wireless module which has a semiconductor device or the like mounted on a board.

### BACKGROUND ART

As a circuit module having a circuit formed using a board, a circuit module is known in which a plurality of boards having active devices and passive devices mounted thereon are arranged to face each other and electrically connected together, and the space between the boards is sealed with resin is known. For example, Patent Literature 1 discloses a wireless module of a semiconductor apparatus having an antenna and a circuit mounted thereon.

In the semiconductor apparatus of Patent Literature 1, an antenna is formed on one surface of a silicon board, a semiconductor device as an active device is mounted on the other surface of the silicon board, and the antenna and the semiconductor device are electrically connected together through a through-via passing through the silicon board. A passive device is mounted on one surface of a wiring board formed separately from the silicon board, and the wiring board and the silicon board are electrically connected together through a connecting member provided between one surface of the wiring board and the other surface of the silicon board.

### CITATION LIST

### Patent Literature

Patent Literature 1: JP-A-2009-266979

### SUMMARY OF INVENTION

### Technical Problem

If a high-frequency wireless module, in particular, a millimeter-wave band wireless module is realized by the configuration of the related art as described above, a problem of impedance mismatching occurs.

The present disclosure has been accomplished in consideration of the above-described situation, and an object of the present disclosure is to suppress a loss due to impedance discontinuity and radiation when configuring a wireless module for a high frequency band.

### Solution to Problem

A wireless module according to the present disclosure includes: a first board on which a mounting component of a wireless circuit is mounted; a second board which is laminated and disposed on the first board; a connecting member which forms a gap allowing mounting of the mounting component between the first board and the second board, the connecting member electrically connecting the first board and the second board; and a conductive member which is arranged so that a signal path of the connecting member has predetermined impedance.

### Advantageous Effects of Invention

According to the present disclosure, when configuring a wireless module for a high-frequency band, it is possible to suppress a loss due to impedance discontinuity and radiation.

### BRIEF DESCRIPTION OF DRAWINGS

In FIG. 1, (A) to (C) show the configuration of a wireless module according to a first embodiment of the present disclosure, and specifically, (A) is a cross-sectional view, (B) is a plan view when viewed from the top of a second board, and (C) is a plan view when viewed from the top in a state where a second board is removed.

In FIG. 2, (A) and (B) show the configuration of a wireless module according to Modification 1 of the first embodiment, and specifically, (A) is a plan view when viewed from the top of a second board, and (B) is a plan view when viewed from the top in a state where a second board is removed.

In FIG. 3, (A) and (B) show the configuration of a wireless module according to Modification 2 of the first embodiment, and specifically (A) is a cross-sectional view, and (B) is a plan view when viewed from the top in a state where a second board is removed.

FIG. 4 shows the configuration of a wireless module according to Modification 3 of the first embodiment, and is a plan view when viewed from the top in a state where a second board is removed.

FIG. 5 shows the configuration of a wireless module according to Modification 4 of the first embodiment, and is a plan view when viewed from the top of a second board.

FIG. 6 shows the configuration of a wireless module according to Modification 5 of the first embodiment, and is a plan view when viewed from the top of a second board.

In FIG. 7, (A) and (B) show the configuration of a wireless module according to a second embodiment of the present disclosure, and specifically, (A) is a plan view when a first board is viewed from the top, and (B) is a cross-sectional view.

FIG. 8 is a plan view showing the configuration of a wireless module according to a modification of the second embodiment.

FIG. 9 is a perspective view showing Configuration Example 1 of a wireless module according to a third embodiment of the present disclosure.

FIG. 10 is a perspective view showing Configuration Example 2 of the wireless module according to the third embodiment: of the present disclosure.

FIG. 11 is a perspective view showing Configuration Example 3 of the wireless module according to the third embodiment of the present disclosure.

FIG. 12 is a perspective view showing Configuration Example 4 of the wireless module according to the third embodiment of the present disclosure.

FIG. 13 is a cross-sectional side view showing a configuration example of a wireless module according to a fourth embodiment of the present disclosure.

FIG. 14 is a cross-sectional side view showing a configuration example of a wireless module according to a fifth embodiment of the present disclosure.

FIG. 15 is a top view showing a first example of the positional relationship between an antenna unit and a waveguide unit of the wireless module according to the fifth embodiment: of the present disclosure.

FIG. 16 is a top view showing a second example of the positional relationship between an antenna unit and a waveguide unit of the wireless module according to the fifth embodiment of the present disclosure.

FIG. 17 is a top view showing a third example of the positional relationship between an antenna unit and a waveguide unit of the wireless module according to the fifth embodiment: of the present disclosure.

### DESCRIPTION OF EMBODIMENTS

(Background to Aspect of the Present Disclosure)

As an example of the configuration of a wireless module, a configuration is made, in which an active device and a passive device are mounted on a first board, a second board having an antenna or the like formed thereon is arranged to face the first board, and the two boards are electrically connected together by a connecting member. In this configuration, a semiconductor device (IC or the like) and passive device, such as a chip capacitor or a chip resistor, are mounted on the first board, and a connecting member such as a solder-plated Cu (copper) core ball is mounted on the second board. The mounting surfaces of the first board and the second board are arranged to face each other, the solder of the connecting member is molten and electrically connected to the first board, and mold resin is filled in a buried layer having a component between the boards to seal the space between the boards with resin. Accordingly, a wireless module in which a plurality of boards are laminated is realized.

If a high-frequency wireless module, in particular, a millimeter-wave band wireless module is realized by the configuration as described above, a problem of impedance mismatching occurs. In a high-frequency band, such as a millimeter-wave band, since a connecting member such as a Cu core ball and wiring pads of a first board and a second board having the connecting member mounted thereon are large with respect to a wavelength, a loss due to impedance discontinuity and radiation increases.

For example, if a dielectric thickness (the thickness of an insulating member of the board) between a layer of a signal line on the board and a ground (GND) layer is 50 μm, and a dielectric constant is about 3 to 4, the wiring width of 50Ω impedance which is generally used as input/output impedance of a high-frequency IC is substantially 50 μm or smaller than 50 υm. In contrast, when a Cu core ball is used as a connecting member, if the height of a component which is mounted in the buried layer between the boards is, for example, 200 μm, it is necessary that the diameter of the Cu core ball is substantially 250 μm, and the size of the wiring pad on the board, on which the component is mounted, is equal to or greater than 250 μm. Since the diameter of the Cu core ball is equal to or greater than five times the wiring width 50 μm, and impedance is capacitive in which a real component is small and an imaginary component is large, a loss due to impedance discontinuity and radiation occurs between the Cu core ball and the wiring.

In consideration of the above-described situation, in the present disclosure, a wireless module which is able to suppress a loss due to impedance discontinuity and radiation when configuring a wireless module for a high-frequency band is illustrated.

### Embodiments of the Present Disclosure

In the following embodiments, as an example of a wireless module according to the present disclosure, several configuration examples of a wireless module which is used in a high-frequency band, such as a millimeter-wave band of 60 GHz, and has an antenna and a semiconductor device mounted thereon will be described.

### First Embodiment

A first embodiment shows a configuration example where a Cu core ball is used as a connecting member which electrically connects board).

In a high-frequency band, such as a millimeter-wave band, when a Cu core ball is used as a connecting member in a wireless module in which a plurality of boards are laminated, a Cu core ball and a wiring pad of a board on which the Cu core ball is mounted, increase in size with respect to a wavelength. That is, since the Cu core ball and the wiring pad of the board becomes greater in size than the wiring width of 50Ω impedance on the board, a loss due to impedance discontinuity and radiation increases.

For example, if the height of a component mounted in a buried layer between the boards is, for example, 200 μm, it is necessary that the diameter of the Cu core ball is substantially 250 μm, and the size of the wiring pad on the board, on which the Cu core ball is mounted, is equal to or greater than 250 μm. If a dielectric thickness (the thickness of an insulating member of the board) between a layer of a signal line on the board and a ground (GND) layer is 50 μm, and a dielectric, constant is about 3 to 4, the wiring width of 50Ω impedance which is generally used as input/output impedance of a high-frequency IC is substantially 50 μm or smaller than 50 μm. Accordingly, the size (about 250 μm) of the Cu core ball and the wiring pad of the board becomes greater than the wiring width (about 50 μm) of the board, and impedance mismatching occurs.

Accordingly, in this embodiment, a wireless module is configured such that a conductor of a Cu core ball of 250 μm operates as a conductor of 50Ω impedance, thereby suppressing a loss due to impedance discontinuity and radiation.

Impedance of the conductor is determined by the distance from the ground and the dielectric constant of a dielectric, between the conductor and the ground. Accordingly, in order that a conductor of 250 μm which becomes a connecting member has 50Ω, it should suffice that a conductive member which becomes the ground is provided at a place separate away from the connecting member by 250 μm. The appropriate distance between the connecting member and the conductive member changes depending on the size of the connecting member and the dielectric constant between the members.

In FIG. 1, (A) to (C) show the configuration of a wireless module according to the first embodiment of the present disclosure, and specifically, (A) is a cross-sectional view, (B) is a plan view when viewed from the top of a second board, and (C) is a plan view when viewed from the top in a state where a second board is removed.

A wireless module of this embodiment includes a first board 11 as a main board and a second board 12 as a sub-board. The first board 11 and the second board 12 are formed of, for example insulating material of a dielectric having a dielectric constant of about 3 to 4. On one surface of the first board 11, a wiring pattern 15 formed of a copper foil or the like is provided, and mounting components of a wireless circuit, for example, a semiconductor device (IC or the like) 13 as an active device and a passive device 14, such as a chip capacitor or a chip resistor, are mounted, thereby forming a wireless circuit. A wiring pad 19 for electrically connecting a connecting member 18 is provided on the first board 11.

On one surface of the second board 12, a sheet-like ground pattern 16 formed of a copper foil and a circular wiring pad 17 are formed, and a connecting member 18, such as a Cu core ball, solder-plated to the wiring pad 17 is mounted. On the other surface of the second board 12, for example, a pad-like antenna 20 formed of a copper foil is formed and electrically connected to the wiring pad 17 on one surface of the second board 12 by a through-via 21.

One surface of the first board 11 and one surface of the second board 12 are arranged to face each other, and the solder of the connecting member 18 is molten and connected to the wiring pad 19 of the first board 11, whereby the second board 12 is electrically connected to the first board by the connecting member 18. At this time, the connecting member 18 becomes a signal transmission path (signal line path) between the wireless circuit of the first board 11 and the antenna 20 of the second board 12. The connecting member 18 is provided so as to form a gap allowing the mounting of a mounting component., such as the semiconductor device 13, between the first board 11 and the second board 12. For example, seal resin 22 of mold resin is filled in the buried layer having the semiconductor device 13, the passive device 14, and the like between the first board 11 and the second board 12 to seal the gap between the boards.

Laterally to the connecting member 18, a conductive member 23 for impedance adjustment as an end surface electrode is provided at a position at a predetermined distance from the connecting member 18. The conductive member 23 is formed by carrying out conductive plating on the lateral end surface of the wireless module. As the conductive member 23, various members, such as a thin film or a flat member, may be used insofar as the members are conductive. The conductive member 23 is electrically connected to a ground pattern 24 formed on the first board 11 and functions as a ground electrode. For example, when conductive plating is provided on the lateral end surface of the wireless module to perform wiring, a shield technique which is performed against EMC may be applied.

For example, when the diameter of the connecting member 18 formed of the Cu core ball is 250 μm, the connecting member 18 is arranged at a position at a distance of about 250 μm from the conductive member 23 on a module end surface on which the conductive member 23. Accordingly, in the connecting member 18 as the signal line path between the boards, a transmission line path having a vertical structure in the board thickness direction can be configured with the ground electrode by the conductive member 23 formed on the module end surface. With the transmission line path having the vertical structure, it is possible to decrease a parasitic capacitive component between the connecting member 18 and the wiring of the board.

As shown in (A) to (C) of FIG. 1, the connecting member 18 and the conductive member 23 are arranged such that the diameter a of the connecting member 18 is substantially the same as the distance b between the connecting member 18 and the conductive member 23. At this time, the conductive member 23 is arranged such that the signal path of the connecting member 18 has predetermined impedance (in this example, 50Ω). As shown in (B) and (C) of FIG. 1, while the diameter a of the connecting member 18 is greater than the wiring width d of the first board 11 and the second board 12, the conductive member 23 is provided at a position at an appropriate distance b, whereby the connecting member 18 can be seen as a conductor of 50Ω impedance.

In this way, according to the configuration of this embodiment., impedance of the connecting member 18 which electrically connects the boards is equal to the board-side wiring, whereby it is possible to take impedance matching between the connecting member 18 and the wirings of the first board 11 and the second board 12 and to suppress a loss due to impedance discontinuity and radiation.

In FIG. 2, (A) and (B) show the configuration of a wireless module according to Modification 1 of the first embodiment, and specifically, (A) is a plan view when viewed from the top of a second board, and (B) is a plan view when viewed from a top in a state where a second board is removed.

In Modification 1 of the first embodiment, ground Cu core balls are arranged as conductive members 25 on both sides of a signal Cu core ball provided as a connecting member 18. The conductive member 25 formed of the ground Cu core ball may be provided on either side of the connecting member 18. The other configuration is the same as in the first embodiment shown in FIG. 1(A), and description thereof will not be repeated.

The conductive members 25 are connected to wiring pads 26 provided on the first board 11 and electrically connected to a conductive member 23 as a ground electrode through ground patterns 27. The conductive member 25 may not be connected to the conductive member 23. It is more effective that the conductive member 25 is connected to the conductive member 23.

In this way, in Modification 1, the ground Cu core balls are provided in the periphery of the Cu core ball, and the connecting member 18 as the signal path between the boards is covered in a concave shape with the conductive members 23 and 25 as the ground. Accordingly, radiation from the connecting member 18 is reduced, thereby further reducing a loss during signal transmission.

In FIGS. 3, (A) and (B) show the configuration of a wireless module according to Modification 2 of the first embodiment, and specifically, (A) is a cross-sectional view, and (B) is a plan view when viewed from the top in a state where a second board is removed.

In Modification 2 of the first embodiment, compared to Modification 1 described above, the connection configuration of the wiring pads 26 connecting the conductive members 25 formed of the ground Cu core balls and the ground pattern 24 is changed.

In the first embodiment shown in FIG. 1(A), the ground pattern 24 of the first board 11 and the conductive member 23 as the ground electrode are connected together in the end surface of the first board 11. In Modification 1 of the first embodiment shown in FIG. 20, the ground wiring pads 26 on the first board 11 are connected to the conductive member 23 through the ground patterns 27.

In Modification 2, vias 101 connecting the wiring pads 26 and the ground pattern 24 are provided in the first board 11. A plurality of vias 101 are provided for the respective wiring pads 26, and the wiring pad 26 is electrically connected to the ground pattern 24 by a plurality of vias 101.

In this was, in Modification 2, the ground wiring pads 26 are connected to the ground pattern 24 through the ground patterns 27 and the conductive member 23, and the wiring pads 26 and the ground pattern 24 are connected through a short path by the vias 101. Accordingly, a potential difference by a resistive component and a parasitic component on the ground decreases, and a stable ground potential is obtained.

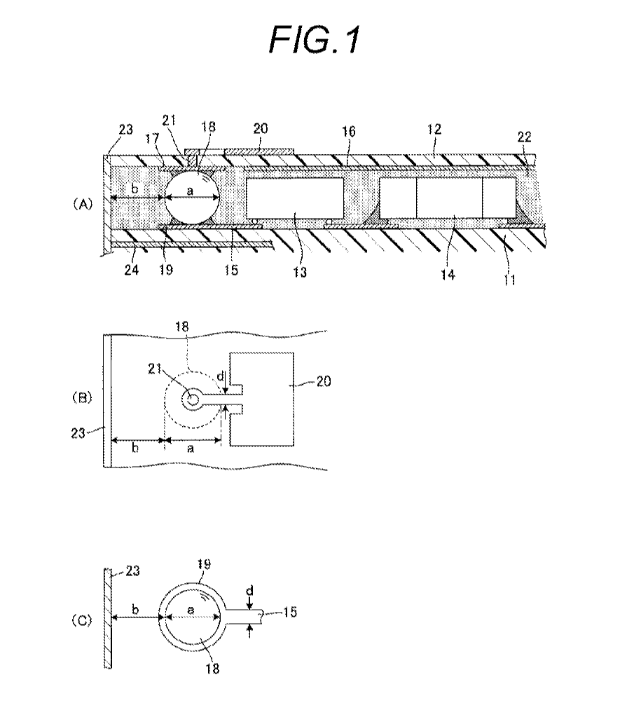

FIG. 4 shows the configuration of a wireless module according to Modification 3 of the first embodiment, and is a plan view when viewed from the top in a state where a second board is removed.

In Modification 3 of the first embodiment, compared to Modification 2 described above, the configuration of a wiring pad 26 is changed. In Modification 2 of the first embodiment shown in FIG. 3(R), a wiring pad 26 and a conductive member 23 are connected by a line path of a ground pattern 27.

In Modification 3, a ground pattern 102 by a large planar pattern (solid pattern) is provided on the first board 11 and includes the functions of a wiring pad 26 and a ground pattern 27. Conductive members 25 formed of ground Cu core balls and a conductive member 23 as a ground electrode are connected to the ground pattern 102. The ground pattern 102 has a shape of surrounding the vicinity of a wiring pad 19 to which a connecting member 18 by a signal Cu core ball is connected.

In this way in Modification 3, the ground pattern 102 by the planar pattern is provided instead of the ground wiring pad 26, thereby stabilizing a ground potential and increasing a shield effect of a signal line.

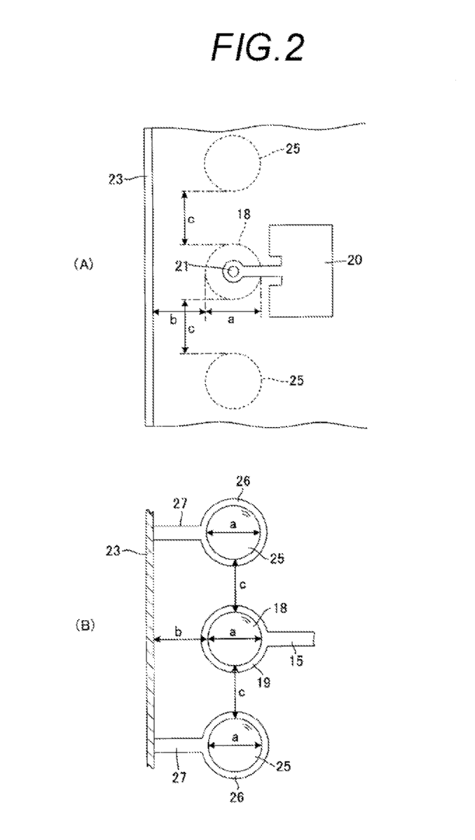

FIG. 5 shows the configuration of a wireless module according to Modification 4 of the first embodiment, and a plan view when viewed from the top of a second board.

In Modification 4 of the first embodiment, compared to the first embodiment and Modification 1 described above, the arrangement configuration of a through-via 21 to which an antenna 20 is connected is changed. In the first embodiment shown in FIG. 1(A), a configuration is made, in which a connecting member 18 is connected to the antenna 20 through a wiring pad 17 and a through-via 21, and a signal is transmitted from the connecting member 18 to the antenna 20.

In Modification 4, on the second board 12, the through-via 21 is provided to be deviated (offset) at a position out of the wiring pad 17, a connecting member-side wiring 111 extends from the wiring pad 17, and the connecting member-side wiring 111 is connected to the through-via 21. On the other surface of the second board 12, the pad-like antenna 20 is connected to the through-via 21.

In this way, in Modification 4, for example, the signal connecting member 18 through which, for example, a high-frequency signal in a millimeter-wave band of 60 GHz or the like is transmitted is configured so as not to be located on the through-via 21, whereby the filling of the through-via 21 can be made using a simple material compared to a case where the connecting member 18 is directly mounted, for example, solder resist.

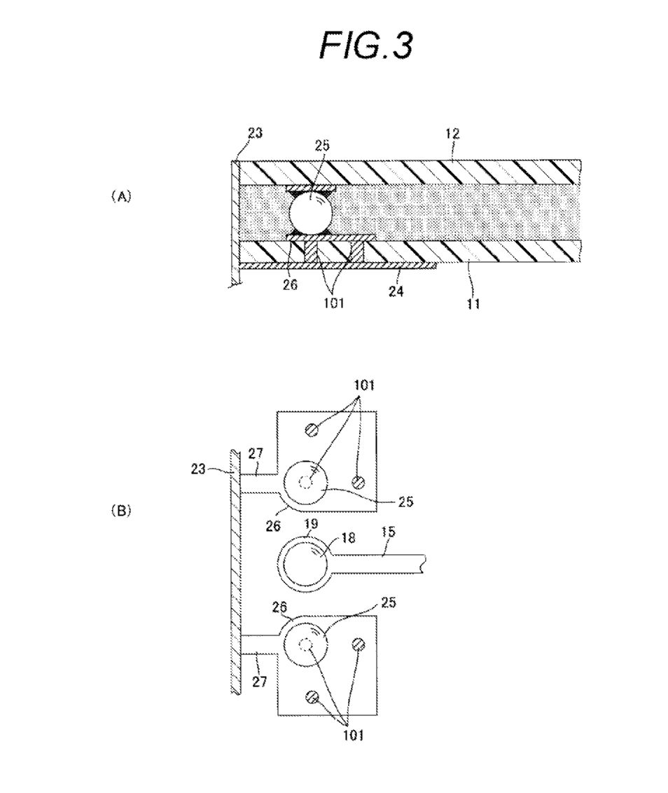

FIG. 6 shows the configuration of a wireless module according to Modification 5 of the first embodiment, and is a plan view When viewed from the top of a second board.

In Modification 5 of the first embodiment, compared to Modification 4 described above, the configuration in the periphery of a through-via 21 is changed. In Modification 5, on the second board 12, an arc-like ground pattern 112 is provided so as to surround the vicinity of the opposite surfaces of the signal connecting member 18 and the wiring pad 17. The ground pattern 112 is substantially formed in a C shape so as to surround the vicinity of the through-via 21. A plurality of vias 113 are provided in the ground pattern 112, and electrically connected to the ground pattern of the second board 12 by the vias 113.

In this way, in Modification 5, the ground pattern 112 is provided so as to surround the wiring pad 17 and the through-via 21 through which a signal is transmitted, thereby reducing leakage of an electromagnetic field. The ground pattern and the signal line are at a specific interval of, for example, 100 μm to 200 μm, making it possible to measure a signal using a high-frequency probe.

### Second Embodiment

In the first embodiment, the ground electrode of the end surface electrode and/or the ground Cu core ball are provided in the periphery of the connecting member formed by the signal Cu core ball, thereby adjusting impedance of the connecting member. A second embodiment shows a configuration example where a conductive member of a dedicated component is arranged in the periphery of a connecting member.

In FIG. 7, (A) and (B) show the configuration of a wireless module according to a second embodiment of the present disclosure, and specifically, (A) is a plan view when a first board is viewed from the top, and (B) is a cross-sectional view.

A conductive member 31 made of a quadrangular frame-shaped metal material is arranged so as to surround the vicinity of a signal Cu core ball provided as a connecting member 18. The conductive member 31 is mounted on the first board 11 or the second board 12. In the example of the drawing, the conductive member 31 is mounted on the second board 12 and electrically connected to a ground pattern 16 of the second board 12. The conductive member 31 is not limited to a conductive member entirely formed of a metal material, but a conductive member in which a conductor, such as metal plating, is covered on the outer surface of a member, such as resin, may be used as the conductive member 31. The other configuration is the same as in the first embodiment shown in FIG. 1(A), and description thereof will not be repeated.

As shown in (A) and (B) of FIG. 7, the conductive member 31 is arranged with respect to the connecting member 18 such that the diameter a of the connecting member 18 is substantially the same as the distance b between the connecting member 18 and the conductive member 31. For example, when the diameter of the connecting member 18 formed of the Cu core ball is 250 μm, the conductive member 31 is formed and arranged such that the distance between the inner wall of the conductive member 31 and the connecting member 18 becomes about 250 μm. Accordingly, impedance of the connecting member 18 can be, for example, 50Ω which is equal to that of the board-side wiring.

By mounting the frame-shaped conductive member 31 as a component, the conductive member 31 functions as the ground for the center connecting member 18 forming the signal line path, and becomes a transmission path configuration in which the signal line path between the boards is similar to a coaxial structure. As shown in FIG. 7(B), the conductive member 31 may be configured such that a notch 32 is provided in a portion, through which the wiring pattern 15 having the connecting member 18 mounted thereon from the wiring pad 19 passes, is provided so as not to interfere with the wiring, thereby reducing coupling to the signal line path.

In this way, according to the configuration of this embodiment, as in the first embodiment, it is possible to take impedance matching between the connecting member 18 and the wirings of the first board 11 and the second board 12, and to suppress a loss due to impedance discontinuity and radiation.

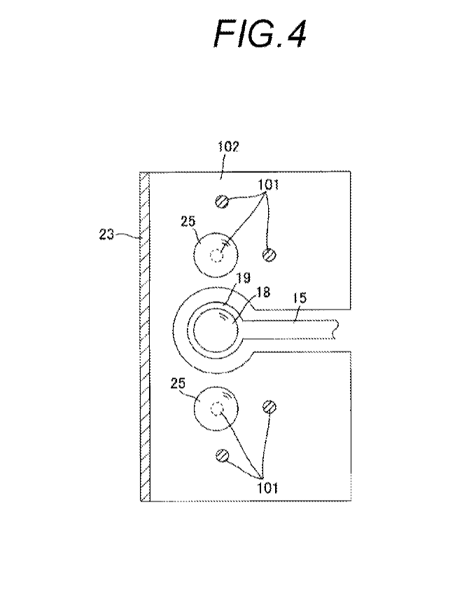

FIG. 8 is a plan view showing the configuration of a wireless module according to a modification of the second embodiment.

In the modification of the second embodiment, a frame-shaped conductive member 35 which surrounds a large area on a board of a wireless module is provided. The conductive member 35 of the modification is configured so as to surround the vicinity of the connecting member 18 and so as to surround the components, such as the semiconductor device 13 and the passive device 14 mounted on the board. The conductive member 35 is mounted on the first board 11 or the second board 12 and is electrically connected to the ground pattern.

In this modification, it is possible to increase a heat dissipation effect and an EMC effect by the conductive member 35 surrounding the components on the board along with the connecting member 18.

### Third Embodiment

A third embodiment shows a configuration example where the configuration of a connecting member itself is changed and a component having a different structure is provided.

When a Cu core ball is used as a connecting member, the diameter of the Cu core ball is determined by the height of a component arranged in the buried layer between the boards. In this case, since the entire Cu core ball is a uniform conductor, and a signal passes through the entire conductor, impedance discontinuity occurs due to a difference in dimension from the wiring on the board.

In the structure of a circuit module in which a plurality of boards are laminated, since strength as a module having a first board and a second board laminated therein is maintained by seal resin filled in the buried layer, the Cu core ball gives a role of providing electrical conduction between the first board and the second board. While the Cu core ball has a spherical shape such that the connecting member can be arranged at a predetermined position without regard to the direction of the connecting member, in general, components having different aspect ratios are mounted on a board in a desired direction, and the spherical shape is not essential for realizing a laminated structure of a plurality of boards.

Accordingly, in this embodiment, several configuration examples where impedance discontinuity does not occur while giving a role of “creating a gap preventing contact with a component.” arranged in the buried layer.

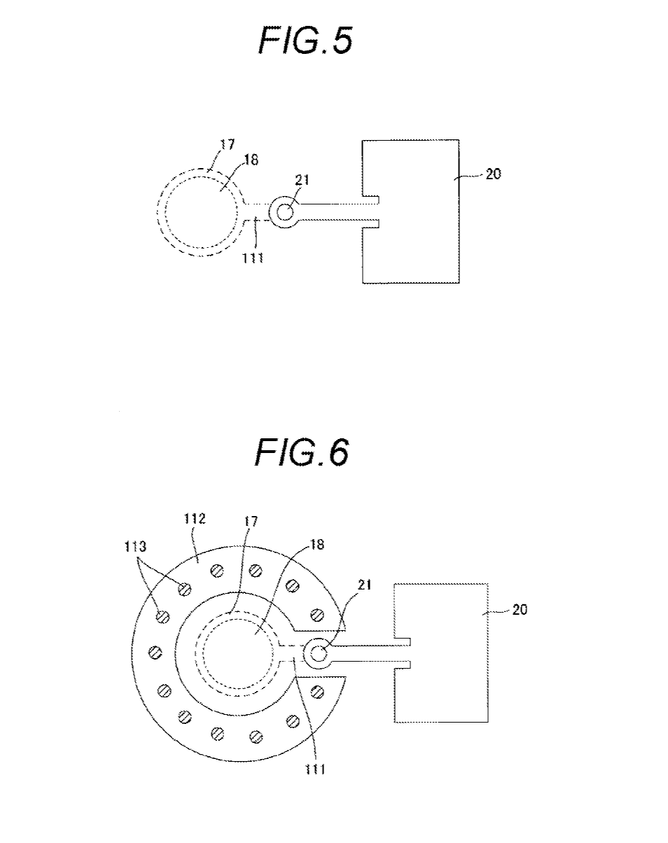

FIG. 9 is a perspective view showing Configuration Example 1 of a wireless module according to the third embodiment of the present disclosure. Configuration Example 1 is an example where a cylindrical connecting member 41 is provided instead of a Cu core ball.

The connecting member 41 is formed in a cylindrical shape and has a cylindrical signal line conductor 42 forming the signal line path in the center portion, and a ground conductor 44 is provided in a circular shape in the outer circumferential portion of a cylinder through a circular tube-shaped insulating member 43. That is, the connecting member 41 is a coaxial component for signal transmission. The ground conductor 44 functions as a conductive member which adjusts impedance of the signal line conductor 42. With this coaxial structure, it is possible to decrease a parasitic capacitive component between the connecting member 41 and the wiring of the board.

Here, a configuration is made such that the diameter al of the signal line conductor 42 is substantially equal to the distance b1 between the signal line conductor 42 and the ground conductor 44. The connecting member 41 is provided so as to form a gap allowing the mounting of a mounting component of a semiconductor device between the first board and the second board. Though not shown, in a state where the connecting member 41 is mounted on the board, the signal line conductor 42 is connected to the wiring pattern of the board, and the ground conductor 44 is connected to the ground pattern of the board. The other configuration is the same as in the first embodiment shown in FIG. 1(A), and description thereof will not be repeated.

For example, if a semiconductor device is mounted on the first board, the wiring pattern and the ground pattern are formed on the first board such that the connecting member 41 of the coaxial component is connected to a lead line from the semiconductor device. That is, on the first board, a wiring pattern of a signal line corresponding to the signal line conductor 42 of the center portion of the connecting member 41 and a ground pattern corresponding to the ground conductor 44 in the periphery of the wiring pattern are formed.

Accordingly, the coaxial signal line and the ground are connected together, and a signal is transmitted from the transmission line path having a planar structure on the board to a coaxial transmission path of the connecting member 41, thereby decreasing impedance discontinuity. A notch 45 may be provided in the ground conductor 44 formed in the outer circumferential portion of the connecting member 41 such that the signal line path of the board does not come into contact with the ground conductor 44 of the connecting member 41 of the coaxial component.

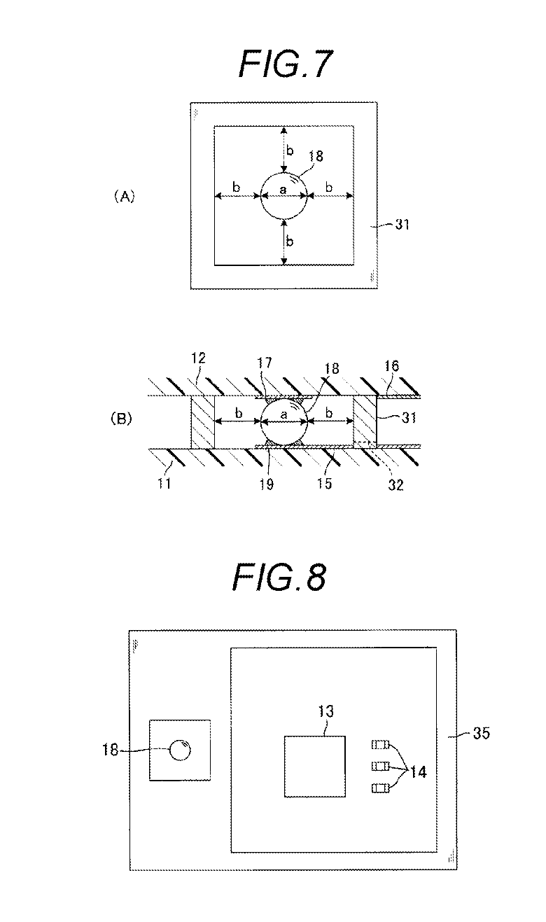

FIG. 10 is a perspective view showing Configuration Example 2 of a wireless module according to the third embodiment of the present disclosure. Configuration Example 2 is an example where a columnar connecting member 51 is provided instead of a Cu core ball.

The connecting member 51 is formed in a prismatic shape, and vias by a plurality of conductors (in the example of the drawing, nine conductors) are provided so as to pass through the opposing end surfaces (in the drawing, the upper and lower surfaces) of the insulating member 53. A signal via 52 through which a signal passes is formed in the center portion, and eight ground vias 54 are formed so as to surround the periphery of the signal via 52. A configuration is made such that the diameter a2 of the signal via 52 is substantially equal to the distance b2 between the signal via 52 and the ground via 54. With the configuration of the connecting member 51, a pseudo coaxial transmission path is formed. The ground vias 54 function as a conductive member which adjusts impedance of the signal via 52.

In Configuration Example 2, since the connecting member can be a rectangular parallelepiped, it becomes easy to pick up a component during mounting. An electrode 55 for position adjustment is provided on the lateral surface of the rectangular parallelepiped of the connecting member 51, thereby reducing positional deviation by a lateral auto-alignment effect during solder mounting.

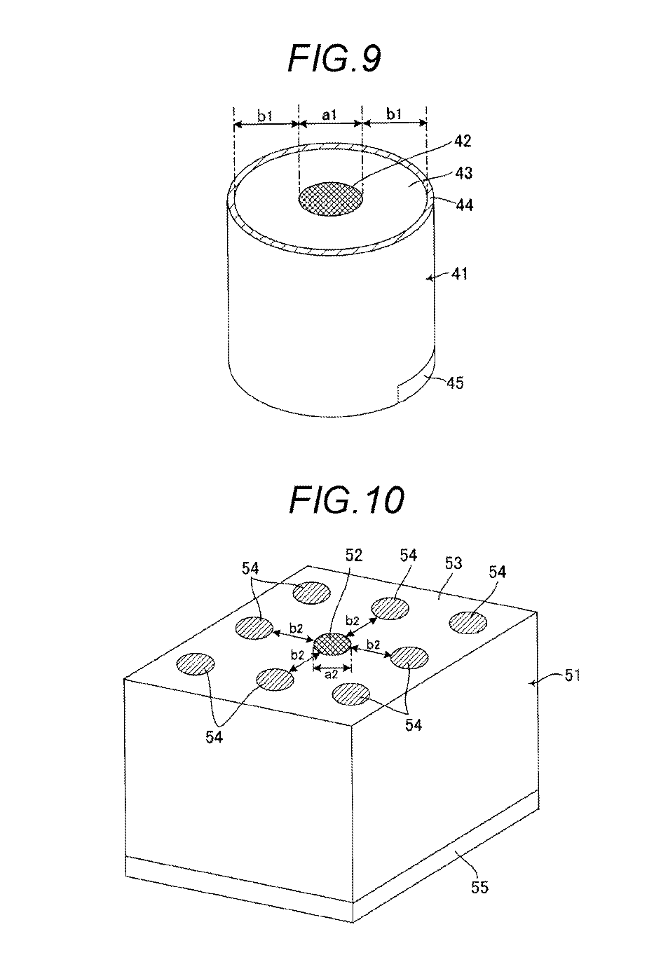

FIG. 11 is a perspective view showing Configuration Example 3 of a wireless module according to the third embodiment of the present disclosure. Configuration Example 3 is an example where a connecting member 61 having a columnar shape with a signal line portion exposed is provided instead of a Cu core ball.

The connecting member 61 has a shape in which the connecting member 41 of Configuration Example 1 is substantially cut in halves in a columnar shape. That is, a columnar signal line conductor 62 which passes through the opposing end surfaces (in the drawing, the upper and lower surfaces) is provided in the central portion of one lateral surface, and a ground conductor 64 is provided on three surfaces excluding a surface on which there is the signal line conductor 62 in the outer circumferential portion of the column through an insulating member 63. One lateral surface of the signal line conductor 62 is exposed to the outside. Here, a configuration is made such that the width a3 of the signal line conductor 62 is substantially equal to the distance b3 between the signal line conductor 62 and the ground conductor 64. The ground conductor 64 functions as a conductive member which adjusts impedance of the signal line conductor 62.

In a state where the connecting member 61 is mounted on the second board 12, the signal line conductor 62 is connected to a wiring pattern 28 of the board, and the ground conductor 64 is connected to a ground pattern 29 of the board. With the configuration in which the signal line conductor 62 is exposed, the wiring pattern 28 on the second board 12 is solder-connected to the signal line conductor 62 on the lateral surface of the connecting member 61, not the signal line conductor 62 of the bottom portion of the connecting member 61, making it easy to confirm defective connection. With the connection of the ground conductor 64, the connecting member 61 can be easily positioned. An electrode 65 for position adjustment is provided on the lateral surface, thereby reducing positional deviation by a lateral auto-alignment during solder mounting.

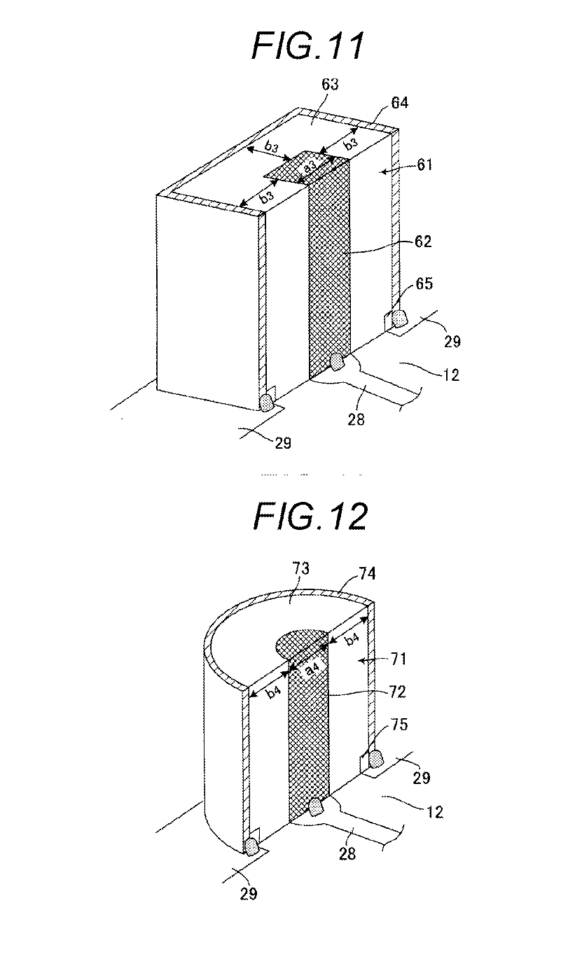

FIG. 12 is a perspective view showing Configuration Example 4 of a wireless module according to the third embodiment of the present disclosure. Configuration Example 4 is an example where a connecting member 71 having a semicylindrical shape with a signal line portion exposed is provided instead of a Cu core ball.

The connecting member 71 has a shape in which the cylindrical connecting member 41 of Configuration Example 1 is substantially cut in halves. That is, a semicylindrical signal line conductor 72 which passes through the opposing end surfaces (in the drawing, the upper and lower surfaces) is provided in the central portion of a lateral surface of a plane, and a ground conductor 74 is provided on the lateral surface of an arc of the semicylinder in an outer circumferential portion through the insulating member 73. One lateral surface of the signal line conductor 72 is exposed to the outside. Here, a configuration is made such that the width a4 of the signal line conductor 72 is substantially equal to the distance b4 between the signal line conductor 72 and the ground conductor 74. The ground conductor 74 functions as a conductive member which adjusts impedance of the signal line conductor 72.

In a state where the connecting member 71 is mounted on the second board 12, the signal line conductor 72 is connected to the wiring pattern 28 of the board, and the ground conductor 74 is connected to the ground pattern 29 of the board. As in Configuration Example 3, with the configuration in which the signal line conductor 72 is exposed, the wiring pattern 28 on the second board 12 is solder-connected to the signal line conductor 72 on the lateral surface of the plane of the connecting member 71, not the signal line conductor 72 in the bottom portion of the connecting member 71, making it easy to confirm defective connection. With the connection of the ground conductor 74, the connecting member 61 can be easily positioned. An electrode 75 for position adjustment is provided on the lateral surface, thereby reducing positional deviation by a lateral auto-alignment during solder mounting.

As described above, in the third embodiment, a connecting member which has a ground conductor and forms a coaxial transmission path is provided instead of a Cu core ball, whereby it is possible to take impedance matching between the connecting member and the wiring of the board while forming a gap allowing the arrangement of a mounting component between the boards. Therefore, it is possible to suppress a loss due to impedance discontinuity and radiation.

### Background to Other Embodiments of the Present. Disclosure

In the related art., an imaging apparatus is known, in which a semiconductor chip having a high-frequency circuit with a transmitter generating a high-frequency signal and a patch antenna formed on one surface of a semiconductor board is mounted on a MMIC (Monolithic. Microwave Integrated Circuits) board (see, for example, Reference Patent Literature 1).
Reference Patent Literature 1: JP-A-2004-205402

There are many cases, however; where the patch antenna and the high-frequency circuit are different in length (height) in the thickness direction of the board. In this case, when mounting a module board on another hoard, if the module board is picked up from the mounting surface of the patch antenna, the tip of a pickup tool (suction apparatus) may interfere with an electronic component for example, the high-frequency circuit including the transmitter).

In consideration with the above situation, the present disclosure exemplifies a wireless module in which, even when an electronic component is mounted on an antenna mounting surface of a wireless module, the wireless module can be easily picked up from the antenna mounting surface.

### Fourth Embodiment

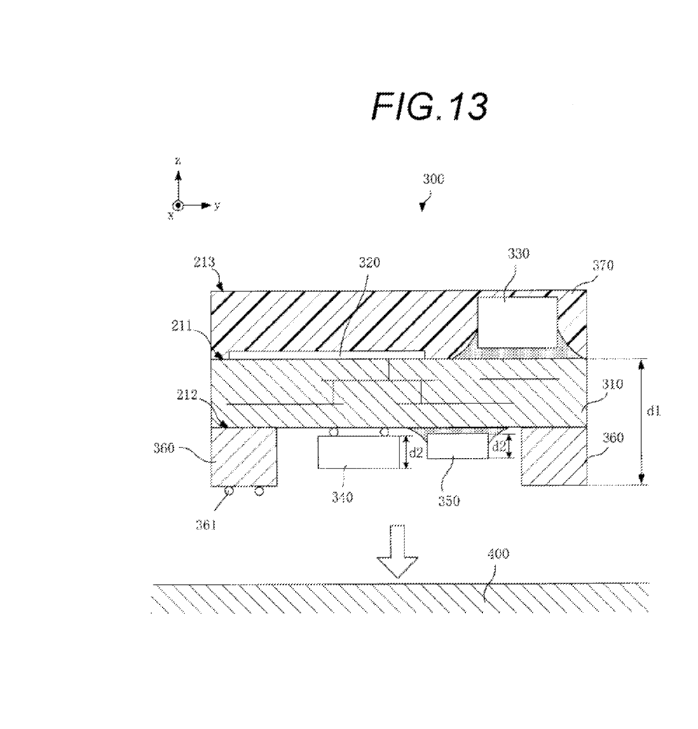

FIG. 13 is a cross-sectional side view showing a configuration example of a wireless module according to a fourth embodiment of the present disclosure.

In a wireless module 300 shown in FIG. 13, a module board 310 is a multi-layered board, and wiring of an IC or the like is performed. 5Electronic components, such as an antenna unit 320 and a Texo 330 (Temperature compensated crystal Oscillator), are mounted on a first surface 211 (in FIG. 13, an upper surface) of the module board 310. Accordingly, the first surface 211 is an antenna mounting surface on which the antenna unit 320 is provided.

The antenna unit 320 is, for example, a patch antenna which is formed by an antenna pattern using wiring. Electronic components, such as a chip component 340 including an RLC and an IC component 350, are mounted on a second surface 212 (in FIG. 13, a lower surface) of the module board 310.

The wireless module 300 is mounted on a set board 400. In this case, the second surface 212 of the module board 310 comes into contact with the mounting surface of the set board 400. A frame board 360 is arranged on the second surface 212 of the module board 310 such that the set board 400 does not come into direct contact with the electronic components mounted on the second surface 212. The frame board 360 has, for example, a square shape and is arranged in a circumferential end portion of the second surface 212 of the module board 310. In this case, the wireless module 300 has a cavity type structure by the module board 310 and the frame board 360. The module board 310 may be constituted by a multi-layered board.

An electrode 361 of the frame board 360 is soldered to the set board 400, and physically and electrically connected to the set board 400. Accordingly, electrical conduction is provided between the frame board 360 as well as the module board 310 and the set board 400 to allow signal transmission.

A length d1 in the board thickness direction (in FIG. 13, z direction) of the module board 310 and the frame board 360 is, for example, about 1 mm. A length d2 in the component thickness direction (in FIG. 13, the z direction) of the chip component 340 or the IC component 350 is, for example, about 0.2 to 0.3 mm. Even if the wireless module 300 including the frame board 360 is mounted on the set board 400, the electronic components mounted on the module board 310 do not come into contact with the set board 400.

On the first surface 211 of the module board 310, the electronic components, such as the antenna unit 320 and the Texo 330, are molded integrally by a mold member (for example, mold resin), and a molded portion 270 is formed. The molded portion 370 surrounds the antenna unit 320 and the peripheral electronic component. There is no particular restriction to the mold member, and it should be noted that a mold member having a small dielectric, tangent (tan δ) has little electric loss in the molded portion 270.

In this embodiment, when the wireless module 300 is mounted on the set board 400, the wireless module 300 is picked up from the first, surface 211 of the module board 310 by a pickup apparatus and mounted on the set board 400. Accordingly, the molded portion 370 is picked up, whereby it is possible to prevent interference during pickup due to the step between the antenna unit 320 and the electronic component provided on the first surface 211, and it becomes easy to pick up the wireless module 300.

It is desirable that a circumferential end surface 213 (ceiling surface) of the molded portion 370 is in parallel to the module board 310 and kept flat. Accordingly, the wireless module 300 can be more easily picked up by absorption.

In this way, the wireless module 300 of this embodiment is a wireless module which is picked up from the first surface 211 as the antenna mounting surface having the antenna unit 320 mounted thereon. The wireless module 300 includes the module board 310 on which the antenna unit 320 is mounted, and the molded portion 370 in which the electronic component including the antenna unit 320 is molded on the first surface 211 of the module board 310. Accordingly, certainty of suction by the pickup tool is improved. That is, even when an electronic, component is mounted on an antenna mounting surface of a wireless module, the wireless module can be easily picked up from the antenna mounting surface.

### Fifth Embodiment

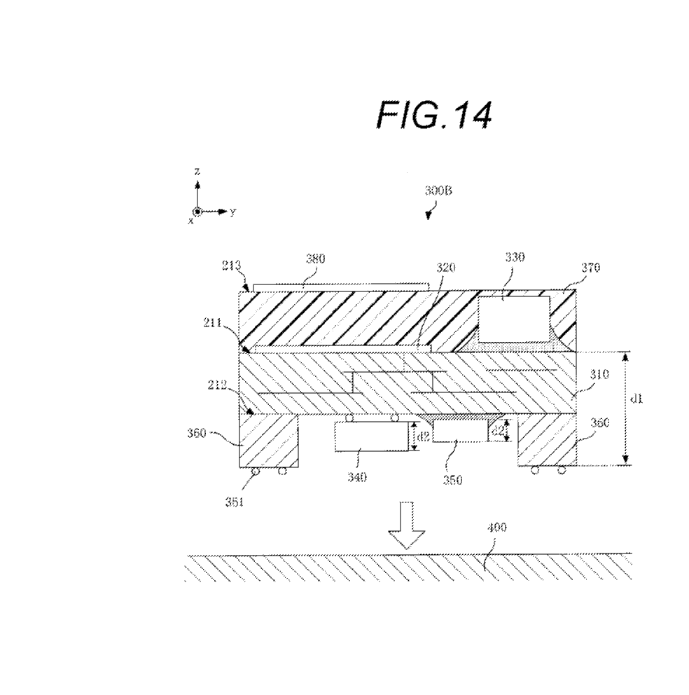

FIG. 14 is a cross-sectional side view showing a configuration example of a wireless module according to a fifth embodiment of the present disclosure.

A wireless module 300B shown in FIG. 14 is different from the wireless module 300 shown in FIG. 13 in that the wireless module 300B includes a waveguide unit 380.

As shown in FIG. 14, the waveguide unit 380 is provided on the circumferential end surface 213 (molded surface) of the molded portion 370 and supports transmission and reception of electric, waves by the antenna unit 320. The waveguide unit 380 is formed by for example, a conductor pattern which functions as a wave director.

Usually, since the mold resin forming the molded portion 370 does not take into consideration the antenna characteristics, the mold resin is an undesirable dielectric when viewed from the antenna unit 320. Although the antenna unit 320 is formed assuming air (dielectric constant ε=1), resin having a dielectric constant. ε=3 to 4 surrounds the antenna, whereby change in the characteristic of the antenna may occur. The wireless module 300B includes the waveguide unit 380, thereby readjusting the antenna characteristic and maintaining the antenna characteristic in a favorable state.

As a position at which the waveguide unit 380 is provided on the molded portion 370, the following three patterns are considered.

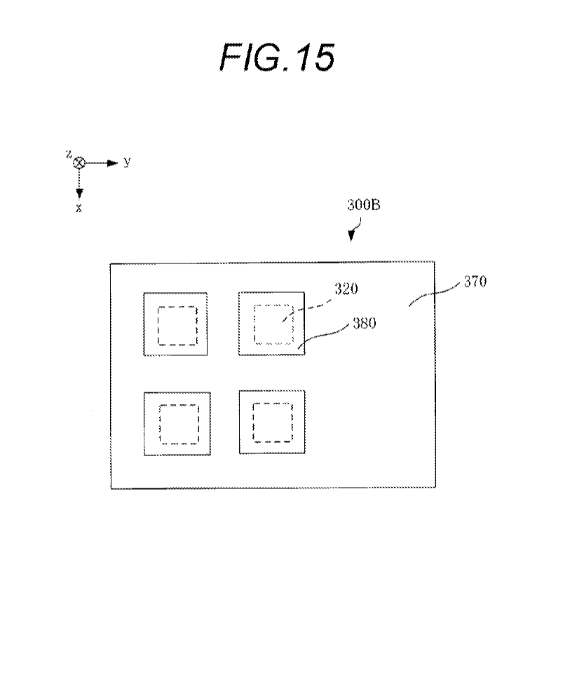

FIG. 15 is a top view showing a first, example of the positional relationship between the antenna unit 320 and the waveguide unit 380 of the wireless module 300B.

In the first example, the waveguide unit 380 is provided at a position facing the antenna unit 320 on the circumferential end surface 213 of the molded portion 370. Accordingly, loss of power transmitted or received through the antenna unit 320 is minimized, and transmission and reception of electric waves can be favorably performed. That is, it is possible to improve certainty of suction by the pickup tool and to maintain the antenna characteristic in a favorable state. On the circumferential end surface 213 of the molded portion 370, the waveguide unit 380 is provided outward of the molded portion 370.

In the example shown in FIG. 15, the antenna unit 320 has a 2×2 array configuration on the first surface 211 of the module board 310. Similarly, the waveguide unit 380 has a 2×2 array configuration on the circumferential end surface 213 of the molded portion 370. The antenna unit 320 and the waveguide unit 380 have a 2×2 array configuration, making it easy to perform phase composition or amplitude composition. The 2×2 array configuration of the antenna unit and the waveguide unit 380 is an example, and a single pattern may be provided or more patterns may be arranged in a lattice shape. The arrangement of multiple patterns ensures a favorable antenna characteristic.

The waveguide unit 380 shown in FIG. 15 is provided, and a pattern which functions as the waveguide unit 380 of the molded portion 370 appropriately changes without redesigning the module board 310, thereby changing an antenna gain or the frequency characteristic of the antenna gain. Although pattern cut of the antenna unit 320 for adjusting manufacturing variation after molding is difficult, this becomes possible by cutting the pattern on the molded portion 370.

Since the molded portion 370 is provided to cause an increase in the thickness (in FIG. 14, the length in the z direction) of a dielectric layer having a dielectric constant higher than air, it is preferable that the waveguide unit 380 is greater than the antenna unit 320. That: is, it is preferable that a region where the waveguide unit 380 is provided on the molded surface of the molded portion 370 is greater than a region where the antenna unit: 320 is provided on the antenna mounting surface. Accordingly, it is possible to further favorably adjust the antenna characteristic.

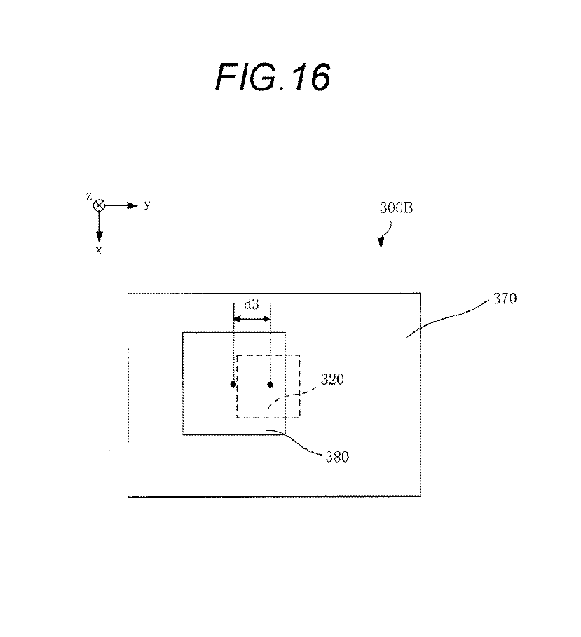

FIG. 16 is a top view showing a second example of the positional relationship between the antenna unit 320 and the waveguide unit 380 of the wireless module 300B.

In the second example, the waveguide unit 380 is provided at a position away from a position facing the antenna unit 320 on the circumferential end surface 213 of the molded portion 370 by a predetermined distance d3. That is, the position on the molded surface of the waveguide unit 380 is deviated (offset) from the position on the antenna mounting surface of the antenna unit 320.

For example, as shown in FIG. 16, when the waveguide unit 380 is on the left side from the antenna unit 320, electric waves are radiated in the left direction. When the waveguide unit 380 is on the right, side from the antenna unit 320, electric waves are radiated in the right direction, in this way, the waveguide unit 380 is arranged so as to be deviated in a direction to radiate electric waves.

The waveguide unit 380 is provided to change the pattern on the circumferential end surface 213 of the molded portion 370 without redesigning the module board 310, thereby changing antenna directionality (tilting beams) Even after the antenna unit 320 is mounted on the module board 310, it is possible to flexibly change antenna directionality.

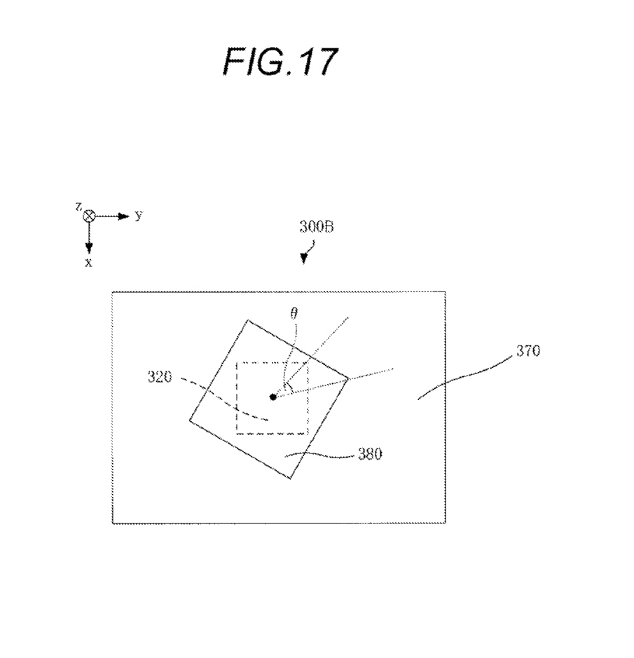

FIG. 17 is a top view showing a third view of the positional relationship between the antenna unit 320 and the waveguide unit 380 of the wireless module 300B.

In the third example, as shown in FIG. 17, on the circumferential end surface 213 of the molded portion 370, the waveguide unit 380 is provided in a region rotated from a region, in which the antenna unit 320 is provided on the antenna mounting surface, by a predetermined rotation angle θ. That is, in FIG. 17, the waveguide unit 380 is mounted on the circumferential end surface 213 in a positional relationship that the direction of a rectangle representing the region of the waveguide unit 380 is rotated from the direction of a rectangle representing the region of the antenna unit 320. Accordingly, it is possible to change the polarization plane (antenna polarization plane) of electric waves radiated from the antenna unit 320.

The position of the waveguide unit 380 on the molded surface and the position (the position on the xy plane) of the antenna unit 320 on the antenna mounting surface are substantially identical. The rotation angle θ is an angle which is less than 90 degrees. The rotation angle θ is adjusted, whereby the antenna polarization plane can be made as a desired polarization plane according to the magnitude of the rotation angle θ. For example, the antenna polarization plane can be changed from a vertical polarization plane to a horizontal polarization plane, can be changed from a horizontal polarization plane to a vertical polarization plane, or can change linearly polarized waves to circularly polarized waves. The change in the antenna polarization plane can be realized by changing the pattern as the waveguide unit 380 on the circumferential end surface 213 of the molded portion 370 without redesigning the module board 310.

Instead of making the positional relationship between the waveguide unit 380 and the antenna unit 320 as a rotation-positional relationship, it may be desired such that the resonance frequency of the waveguide unit 380 and the resonance frequency of the antenna unit 320 are different from each other. With this, it is possible to change the antenna polarization plane.

For example, the resonance frequencies of the antenna unit 320 and the waveguide unit 380 are deviated slightly from each other such that the resonance frequency of the antenna unit 320 becomes 60 GHz and the resonance frequency of the waveguide unit 380 becomes 59.5 GHz, whereby the excitation timing differs slightly. Accordingly, it is possible to change the antenna polarization plane.

(Summary of Aspects of the Present Disclosure)

A wireless module according to a first aspect of the present disclosure includes: a first board on which a mounting component of a wireless circuit is mounted; a second board which is laminated and disposed on the first board; a connecting member which forms a gap allowing mounting of the mounting component between the first board and the second board, the connecting member electrically connecting the first board and the second board; and a conductive member which is arranged so that a signal path of the connecting member has predetermined impedance.

According to the configuration, when configuring a wireless module used for a high-frequency band such as a millimeter-wave band, it is possible to take impedance matching between the signal paths of the connecting member and thereby to suppress a loss due to impedance discontinuity and radiation.

A wireless module according to a second aspect: of the present disclosure is the wireless module according to the first aspect, wherein the connecting member includes a conductor which forms the signal path, and the conductive member is arranged at a position separate by a predetermined distance from the conductor of the connecting member, and is connected to a ground of the first board or the second board.

A wireless module according to a third aspect of the present disclosure is the wireless module according to the second aspect, wherein the connecting member is a member of a conductor, and the conductive member is a separate member different from the connecting member.

A wireless module according to a fourth aspect of the present disclosure is the wireless module according to the second aspect, wherein the connecting member includes a signal line conductor and a ground conductor which is arranged at a position at a predetermined distance from the signal line conductor, and the ground conductor functions as the conductive member.

A wireless module according to a fifth aspect of the present disclosure is the wireless module according to the fourth aspect, including a wiring pad which is connected to the connecting member of the ground conductor and formed on the first board or the second board; and a via which connects the wiring pad and the ground of the first board or the second board.

A wireless module according to a sixth aspect of the present disclosure is a wireless module to be picked up from an antenna-mounting surface on which an antenna unit is provided, the wireless module including: a module hoard on which the antenna unit is mounted; and a molded portion in which an electronic component including the antenna unit is molded in the antenna mounting surface of the module board.

According to the configuration, when an electronic component is mounted on an antenna mounting surface of a wireless module, it is possible to prevent, interference during pickup due to the step between the antenna unit and the electronic component by using the molded portion, whereby the wireless module can be easily picked up from the antenna mounting surface.

A wireless module according to a seventh aspect of the present disclosure is the wireless module according to the sixth aspect, further including a waveguide unit provided at a position facing the antenna unit on circumferential end surface of the molded portion to support transmission and reception of an electric wave by the antenna unit.

A wireless module according to an eighth aspect of the present disclosure is the wireless module according to the seventh aspect, wherein an area of the wave-guide unit, provided on the molded portion is larger than an area of the antenna unit provided on the module board.

A wireless module according to a ninth aspect of the present disclosure is the wireless module according to the sixth aspect, including a waveguide unit provided at a position separate away from a position, by a predetermined distance, facing the antenna unit on a circumferential end surface of the molded portion to support transmission and reception of an electric wave by the antenna unit.

A wireless module according to a tenth aspect of the present disclosure is the wireless module according to any one of the sixth to ninth aspects, wherein the waveguide unit is provided in an area rotated by a predetermined angle from an area of the antenna unit provided in the antenna mounting surface on the circumferential end surface of the molded portion.

A wireless module according to an eleventh aspect of the present disclosure is the wireless module according to any one of the sixth to ninth aspects, wherein a resonance frequency of the waveguide unit and a resonance frequency of the antenna unit are different from each other.

According to the present disclosure, various modifications and applications by those skilled in the art on the basis of the disclosure of the specification and known techniques without departing from the spirit and scope of the present disclosure are also intended by the present disclosure, and included in a scope to be protected. Also, the respective components in the foregoing embodiments may be arbitrarily combined together without departing from the spirit of the disclosure.

The present application is based on Japanese Patent Application No. 2011-265019 filed on Dec. 2, 2011, and Japanese Patent. Application No. 2011-268042 filed on Dec. 7, 2011, the contents of which are incorporated herein by reference.

### INDUSTRIAL APPLICABILITY

The present disclosure has an effect of suppressing a loss due to impedance discontinuity and radiation when configuring a wireless module for a high-frequency band, and is useful as a wireless module or the like in which, for example, a semiconductor device or the like for wireless communication in a millimeter-wave band or the like is mounted.

### REFERENCE SIGNS LIST

11: first board

12: second board

13: semiconductor device

14: passive device

15, 28: wiring pattern

16, 24, 27, 29, 102, 112: ground pattern

17, 19, 26: wiring pad

18, 41, 51, 61, 71: connecting member

20: antenna

21: through-via

22: seal resin

23, 25, 31, 35: conductive member

42, 62, 72: signal line conductor

43, 53, 63, 73: insulating member

44, 64, 74: ground conductor

52: signal via

54: ground via

101, 113: via

111: connecting member-side wiring

211: first surface (antenna mounting surface) of module board.

212: second surface of module board

213: circumferential end surface (molded surface) of molded portion

300, 300B: wireless module

310: module board

320: antenna unit

330: Texo

340: chip component

350: IC component

360: frame board

361: electrode

370: molded portion

380: waveguide unit

400: set hoard

1. A wireless module, comprising:
a first board on which a mounting component of a wireless circuit is mounted;
a second board which is laminated and disposed on the first board;
a connecting member which forms a gap allowing mounting of the mounting component between the first board and the second board, the connecting member electrically connecting the first board and the second board, wherein the connecting member includes a conductor forming a signal path; and
a conductive member which is arranged at a position separate by a predetermined distance from the conductor of the connecting member, the conductive member being connected to a ground of the first board or the second board wherein
the connecting member is connected to the mounting component via a signal line having a predetermined width,
a diameter of the connecting member is greater than e predetermined width of the signal line, and
the predetermined distance between the conductive member and the conductor of the connecting member is substantially the same as the diameter of the connecting member.

2. (canceled)

3. The wireless module according to claim 1, wherein
the connecting member is a member of a conductor, and
the conductive member is a separate member different from the connecting member.

4. The wireless module according to claim 1, wherein
the connecting member includes a signal line conductor and a ground conductor which is arranged at a position at a predetermined distance from the signal line conductor, and the ground conductor functions as the conductive member.

5. The wireless module according to claim 4, comprising:
a wiring pad which is connected to the connecting member of the ground conductor and formed on the first board or the second board; and
a via which connects the wiring pad and the ground of the first board or the second board.

6. The wireless module according to claim 1, wherein
the conductive member is arranged so that the signal path of the connecting member has predetermined impedance.
